(19) United States
(12) Patent Application Publication
(10) Pub. No.: US 2026/0173820 A1
(43) Pub. Date: Jun. 18, 2026

(54) A BASE FLATNESS ADJUSTING ASSEMBLY

(71) Applicant: INNO ROBOTICS INC., Hwaseong-si, Gyeonggi-do (KR)

(72) Inventors: Minji KIM, Suwon-si (KR); Kyu Jung CHO, Hwaseong-si (KR)

(73) Assignee: INNO ROBOTICS INC., Hwaseong-si, Gyeonggi-do (KR)

(21) Appl. No.: 18/711,960

(22) PCT Filed: Nov. 25, 2022
(86) PCT No.: PCT/KR2022/018881

§ 371 Date: May 21, 2024

(30) Foreign Application Priority Data
Nov. 25, 2022 (KR) 10-2022-0160476

(51) Int. Cl. H10P 72/76

(52) U.S. Cl. CPC H10P 72/7624

(57) ABSTRACT

A base flatness adjusting assembly according to an example embodiment refers to a base flatness adjusting assembly installed to support the base comprising, a shaft coupled through the base, a fixed nut coupled to one side of the shaft to fix the shaft to the base, an upper piece plate composed of a through-tube coupled to the base and an upper plate member attached to the lower surface of the base and a lower piece plate installed at a position corresponding to the upper piece plate and supporting the base by coming into contact with the other side of the shaft, wherein the other side of the shaft has a hemispherical shape, and the upper surface of the lower piece plate has a shape selected from the group consisting of a flat, cone, and slot shape at a position in contact with the other side of the hemispherical shaft.

### TECHNICAL FIELD

The present invention relates to a base flatness adjusting assembly, and more particularly, to a base flatness adjusting assembly for adjusting the flatness of a stage for processing a workpiece and a base supporting the same.

### BACKGROUND ART

In general, a table apparatus configured to be movable is configured to be freely movable on the XY plane. The process of processing semiconductor wafers, objects of laser processing, etc. placed on a table requires precise movements that do not allow even minute errors through table control.

A number of movable tables, such as Korean Patent Publication No. 2008-0083297, Korean Patent Publication No. 2000-0006149, and Japanese Patent Publication No. 2005-297189, have at least one movable table disposed at the bottom. The structure is getting bigger.

In addition, the flatness of the stage on which the table is placed and the base supporting the stage must be set according to the installation position, and this setting process is an essential process to ensure the precision of the table's movement. Furthermore, vibrations that may occur due to the movement of the table and such vibrations may accumulate to cause deformation of the base.

Various design changes are being made to reduce vibration, and a solution to fundamental deformation due to stress of the base or stage has not been proposed other than the process of reducing machining errors by installing a separate damping device.

Korean Patent Registration No. 10-1395033 relates to an XY stage of a prefabricated structure composed of a separable or assembling type to cope with the display panel of a large-sized trend, but does not suggest a solution to solve the deformation problem caused by stress that may occur on the actual stage. can't In addition, there is a need for a structure that can be installed while adjusting the flatness relatively easily in various installation environments.

### DISCLOSURE

### Technical Problem

An object of the present invention is to provide a base flatness adjusting assembly capable of easily adjusting flatness and restraining six degrees of freedom.

### Technical Solution

A base flatness adjusting assembly according to an example embodiment refers to a base flatness adjusting assembly installed to support the base comprising, a shaft coupled through the base, a fixed nut coupled to one side of the shaft to fix the shaft to the base, an upper piece plate composed of a through-tube coupled to the base and an upper plate member attached to the lower surface of the base and a lower piece plate installed at a position corresponding to the upper piece plate and supporting the base by coming into contact with the other side of the shaft, wherein the other side of the shaft has a hemispherical shape, and the upper surface of the lower piece plate has a shape selected from the group consisting of a flat, cone, and slot shape at a position in contact with the other side of the hemispherical shaft.

Also, wherein one side of the shaft is formed with a wrench hole for rotating the shaft.

Also, wherein the upper plate member has through-holes formed at positions symmetrical to each other around the through-pipe formed at the center, and rivets are inserted into the through-holes to penetrate the upper plate member and combine with the lower piece plate, and the spring is inserted into the hole and the rivet is installed in the center of the spring.

Also, wherein the rivet is inserted into the insertion groove formed in the lower piece plate and fixed by a fixing member.

A stage according to an example embodiment refers to a stage comprising the base flatness adjusting assembly comprising square base and an upper surface shape of the lower piece plate positioned below the base includes a slot shape and a cone shape, wherein the slot direction of the slot shape is installed so as to face a direction of the lower piece plate having the cone shape.

### Advantageous Effects

According to the base flatness adjusting assembly according to an embodiment of the present invention, the flatness of the base can be easily adjusted.

In addition, by constraining the six degrees of freedom, over-constraining can be prevented and distortion of the plane can be minimized.

A further scope of the applicability of the present invention will become apparent from the detailed description that follows. However, since various changes and modifications within the spirit and scope of the present invention can be clearly understood by those skilled in the art, it should be understood that the detailed description and specific examples such as preferred embodiments of the present invention are given as examples only.

### DESCRIPTION OF DRAWINGS

FIG. 1 is a front view of a base flatness adjusting assembly according to an embodiment of the present invention.

FIG. 2 is a first cross-sectional view of a base flatness adjusting assembly according to an embodiment of the present invention.

FIG. 3 is a second cross-sectional view of a base flatness adjusting assembly according to an embodiment of the present invention.

FIG. 4 is a view showing the shape of the upper surface of the lower piece plate according to the embodiment of the present invention.

FIG. 5 is a perspective view of a stage including a base flatness adjusting assembly according to an embodiment of the present invention.

FIG. 6 is a conceptual diagram illustrating the installation of the lower surface of the base according to an embodiment of the present invention.

### MODES OF THE INVENTION

Specific structural or functional descriptions of the embodiments according to the concept of the present invention disclosed in this specification are only illustrated for the purpose of explaining the embodiments according to the concept of the present invention, and it can be embodied in various forms and is not limited to the embodiments described herein.

Embodiments according to the concept of the present invention can apply various changes and have various forms, so the embodiments are illustrated in the drawings and described in detail in this specification. However, this is not intended to limit the embodiments according to the concept of the present invention to specific disclosure forms, and includes all changes, equivalents, or substitutes included in the spirit and technical scope of the present invention.

Although terms of “first,” “second,” and the like may be used to explain various components, the components are not limited to such terms. These terms are used only to distinguish one component from another component. For example, a first component may be referred to as a second component, or similarly, the second component may be referred to as the first component within the scope of the present invention.

When it is mentioned that one component is “connected” or “joined” to another component, it may be understood that the one component is directly connected or accessed to another component or that still other component is interposed between the two components. In addition, it should be noted that if it is described in the specification that one component is “directly connected” or “directly joined” to another component, still other component may not be present therebetween. Likewise, expressions, for example, “between” and “immediately between” and “adjacent to” and “immediately adjacent to” may also be construed as described in the foregoing.

The terminology used herein is for the purpose of describing particular example embodiments only and is not to be limiting of the example embodiments. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, components or a combination thereof, but do not preclude the presence or addition of one or more other features, integers, steps, operations, elements, components, and/or groups thereof.

Unless otherwise defined herein, all terms used herein including technical or scientific terms have the same meanings as those generally understood by one of ordinary skill in the art. Terms defined in dictionaries generally used should be construed to have meanings matching contextual meanings in the related art and are not to be construed as an ideal or excessively formal meaning unless otherwise defined herein.

Hereinafter, the example embodiments will be described in detail with reference to the accompanying drawings. However, the scope of the claims is not limited to or restricted by such example embodiments.

Like reference numerals refer to like components throughout.

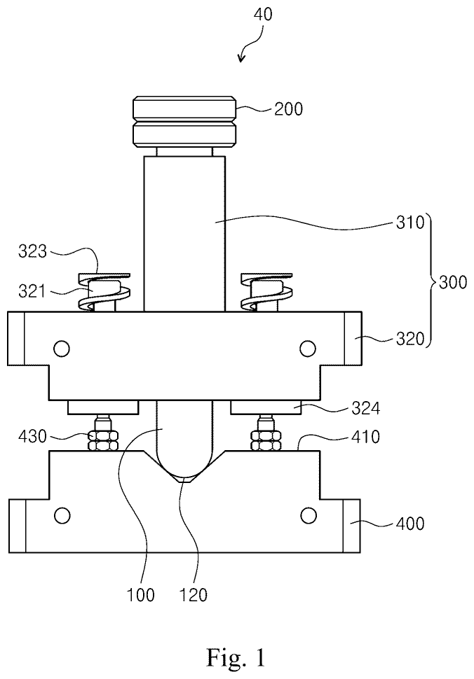

FIG. 1 is a front view of a base flatness adjusting assembly according to an embodiment of the present invention.

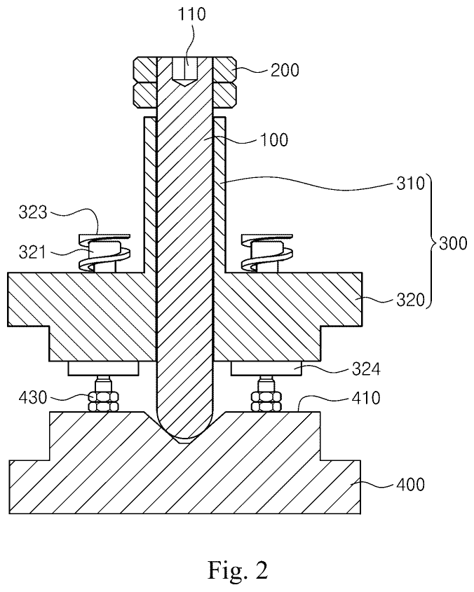

FIG. 2 is a first cross-sectional view of a base flatness adjusting assembly according to an embodiment of the present invention.

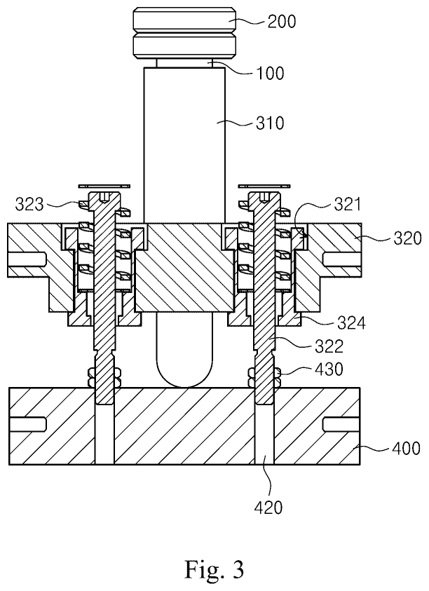

FIG. 3 is a second cross-sectional view of a base flatness adjusting assembly according to an embodiment of the present invention.

As shown in FIGS. 1 to 3, the base flatness adjusting assembly 40 according to the embodiment of the present invention is a base flatness adjusting assembly 40 installed to support the base 10 and a shaft 100 passes through the base 10. A shaft 100 that is coupled to each other, a fixed nut 200 that is coupled to one side of the shaft 100 to fix the shaft 100 to the base 10, and a through-tube 310 that penetrates and couples with the base 10 and an upper piece plate 300 composed of an upper plate member 320 attached to the lower surface of the base 10 and installed at a position corresponding to the upper piece plate 300 to come into contact with the other side of the shaft 100. It includes a lower piece plate 400 supporting the base 10, the other side of the shaft 120 has a hemispherical shape, and the upper surface of the lower piece plate 400 is flat at a position in contact with the other side 120 of the hemispherical shaft. Any one shape selected from the group consisting of a flat, slot, and cone shape is formed.

Shaft 100 according to an embodiment of the present invention is coupled to the base 10 through. The base 10 is made of a metal alloy material, and is particularly made of a hard material that is difficult to bend or break. A hole passing through the base 10 is formed, and the shaft 100 passes through the hole and is coupled.

As shown in FIG. 2, the shaft 100 is made of a solid metal material and has high strength, and a screw thread is formed at the middle end so that the height of the base 10 can be adjusted through rotation.

In addition, a wrench hole 110 for rotating the shaft 100 is formed at one end of the shaft 100. The other side of the shaft 120 is formed in a hemispherical shape, and the other side of the shaft 120 is connected to the lower piece plate 400 to be described below to support the base 10.

The fixed nut 200 performs a function of fixing the shaft 100 and the base 10 by being coupled to one side of the shaft 100. The fixed nut 200 and the shaft 100 are firmly coupled by screwing, but when coupled with the shaft 100, the fixed nut 200 is located on the upper surface of the base 10.

The upper piece plate 300 is composed of a through pipe 310 and an upper plate member 320 integrally formed. The through tube 310 is fitted into a hole formed in the base 10 and the shaft 100 is inserted into a cavity formed inside the through tube 310. On the inner surface of the through-pipe 310, a screw thread that can engage with a screw thread formed on the outer circumferential surface of the shaft 100 is formed, and the upper piece plate 300 rises and falls by the rotation of the shaft 100, and at the same time the base 10 also rises and falls.

As shown in FIG. 3, the upper plate member 320 has through-holes 321 formed at symmetrical positions around the through-pipe 310 formed at the center, and rivets 322 are inserted in the through-holes 321. Rivet 322 penetrates the upper plate member 320 and is combined with the lower piece plate 400, and a spring 323 is inserted into the through hole 321 so that the rivet 322 is attached to the center of the spring 323 is located

In addition, as shown in FIG. 3, it further includes an insertion member 324 inserted into the through hole 321 formed in the top plate member 320, and a rivet 322 and a spring inside the insertion member 324. 323 may be coupled to the lower piece plate 400 by fastening.

The lower piece plate 400 is installed at a position corresponding to the upper piece plate 300 and supports the base 10 by coming into contact with the other side 120 of the shaft.

The upper piece plate 300 and the lower piece plate 400 are made of a metal material that is difficult to break or deform due to the nature of their function and role, and may be made of an alloy material such as the base material.

The lower piece plate 400 includes an insertion groove 420 into which the rivet 322 is inserted, and the rivet 322 is inserted into the insertion groove 420 by the fixing member 430 is fixed at lower the lower piece plate 400.

In the state where the rivet 322 is fastened and the spring 323 is coupled around the rivet 322, the rivet 322 rotates and descends, and the rivet 322 is fastened to the insertion hole 420 of the lower piece plate 400. The upper piece plate 300 and the lower piece plate 400 are firmly coupled. In addition, the spring 323 is a structure that compensates for shaking in the vertical direction with a preload structure.

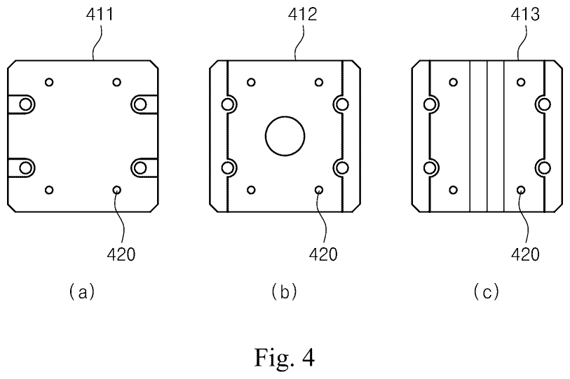

FIG. 4 is a view showing the shape of the upper surface of the lower piece plate according to the embodiment of the present invention.

As described above, the other side of the shaft 100 has a hemispherical shape, and as shown in FIG. 4, the shape of the area where the other side of the shaft come into contact with the lower piece plate is any one shape selected from the group consisting of flat shape (a) (411), cone shape (b) (412) and slot shape (c) (413).

The base flat assembly 40 according to an embodiment of the present invention is the same as when plates such as the base 10 were previously assembled despite repeated separation and coupling, and in order to constrain on the 6-degree of freedom and minimizing warping of the base 10. The base flat assembly 40 use a kinematic mounting structure.

The base 10 according to an embodiment of the present invention needs to suppress linear motion (X, Y, Z) and rotations (roll, pitch, yaw). A rigid structure that is completely fixed in space, despite repeated disassembly and assembly, needs to be suppressed in the 6-DOF. This point is an essential element in semiconductor processes and the like that require high mechanical precision.

A flat 411, cone 412 or slot 413 shape is used on the upper surface 410 of the lower piece plate according to the embodiment of the present invention to suppress unwanted movement.

The flat shape 411 suppresses roll while coming into contact with the hemispherical shaft 100, the cone shape 412 suppresses linear movement in the x, y, and z directions, and the slot shape 413 suppresses pitch and yaw.

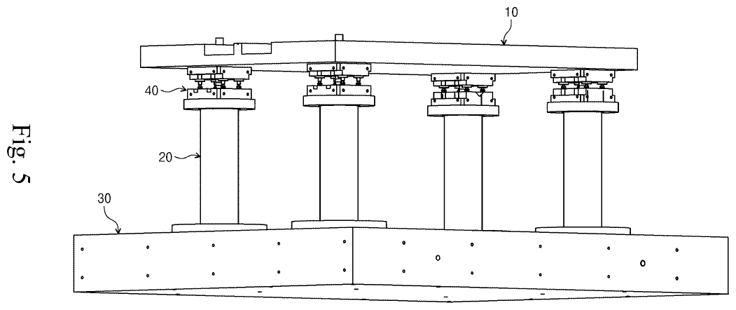

FIG. 5 is a perspective view of a stage including a base flatness adjusting assembly according to an embodiment of the present invention.

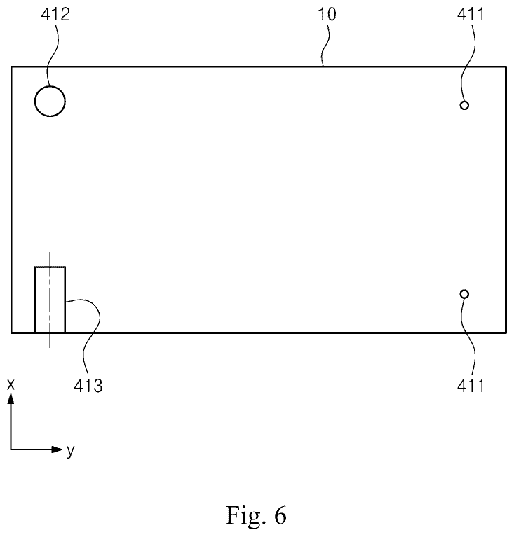

FIG. 6 is a conceptual diagram illustrating the installation of the lower surface of the base according to an embodiment of the present invention.

As shown in FIG. 5, the base flatness adjusting assembly 40 according to the embodiment of the present invention is generally installed at the lower part of the base 10, and is installed at each of the four corners of the rectangular base 10. The installed base flatness adjusting assembly 40 is connected to the support pillar 20 to support the four corners of the base 10, and the support pillar 20 is connected to a solid and rigid structure such as a stone table 30. In addition, an isolator (not shown) for absorbing minute vibrations may be installed.

In addition, various mechanisms for processing a workpiece, such as a linear motor and an XY table, may be mounted on the upper portion of the base shown in FIG. 5.

As shown in FIGS. 5 and 6, the stage including the base flatness adjusting assembly 40 according to an embodiment of the present invention includes a rectangular base 10 and a lower piece plate positioned below the base !0 The shape of the upper surface 410 includes a slot shape 413 and a cone shape 412, and the center line direction of the slot shape 413 is installed toward the lower piece plate 400 having the cone shape 412.

As shown in FIG. 6, when the center line direction of the slot shape 413 is toward the cone shape 412 and the upper surface 410 of the lower piece plate installed at the other two corners has a flat shape 411, 6-degree of freedom is constrained.

Although the present invention has been described with reference to the embodiments shown in the drawings, this is only exemplary, and those skilled in the art will understand that various modifications and equivalent other embodiments are possible therefrom. For example, the described techniques may be performed in an order different from the method described, and/or components of the described system, structure, device, circuit, etc. may be combined or combined in a different form than the method described, or other components may be used. Or even if it is replaced or substituted by equivalents, appropriate results can be achieved. Therefore, the true technical protection scope of the present invention should be determined by the technical spirit of the attached claims.

1. A base flatness adjusting assembly installed to support the base comprising;
a shaft coupled through the base;
a fixed nut coupled to one side of the shaft to fix the shaft to the base;
an upper piece plate composed of a through-tube coupled to the base and an upper plate member attached to the lower surface of the base; and
a lower piece plate installed at a position corresponding to the upper piece plate and supporting the base by coming into contact with the other side of the shaft,
wherein the other side of the shaft has a hemispherical shape, and the upper surface of the lower piece plate has a shape selected from the group consisting of a flat, cone, and slot shape at a position in contact with the other side of the hemispherical shaft.

2. The base flatness adjusting assembly of claim 1,
wherein one side of the shaft is formed with a wrench hole for rotating the shaft.

3. The base flatness adjusting assembly of claim 1,
wherein the upper plate member has through-holes formed at positions symmetrical to each other around the through-pipe formed at the center, and rivets are inserted into the through-holes to penetrate the upper plate member and combine with the lower piece plate, and the spring is inserted into the hole and the rivet is installed in the center of the spring.

4. The base flatness adjusting assembly of claim 3,
wherein the rivet is inserted into the insertion groove formed in the lower piece plate and fixed by a fixing member.

5. A stage comprising the base flatness adjusting assembly of claim 1 comprising;
square base; and
an upper surface shape of the lower piece plate positioned below the base includes a slot shape and a cone shape,
wherein the slot direction of the slot shape is installed so as to face a direction of the lower piece plate having the cone shape.
